(19) United States
(12) Patent Application Publication
(10) Pub. No.: US 2017/0103919 A1
(43) Pub. Date: Apr. 13, 2017

(54) FABRICATION METHOD FOR SEMICONDUCTOR DEVICE

(71) Applicant: DISCO CORPORATION, Tokyo (JP)

(72) Inventor: Youngsuk Kim, Tokyo (JP)

(21) Appl. No.: 15/281,450

(22) Filed: Sep. 30, 2016

(30) Foreign Application Priority Data
Oct. 7, 2015 (JP) 2015-199701

(51) Int. Cl. H01L 21/768; H01L 21/304

(52) U.S. Cl. CPC H01L 21/76898; H01L 21/304

(57) ABSTRACT

A fabrication method for a semiconductor device is provided. The fabrication method for a semiconductor device includes a semiconductor chip arraying step of arraying a plurality of semiconductor chips at given distances on a first face of a substrate that serves as a supporting body, a substrate thinning step of grinding a second face of the substrate at the side opposite to the first face to thin the substrate to a given thickness, a through electrode formation step of forming a through-hole that extends from the second face side to the semiconductor chip at a given position of the thinned substrate and embedding metal into the through-hole to form a through electrode, and a wiring layer formation step of forming a wiring layer at the second face side of the substrate.

### BACKGROUND OF THE INVENTION

Field of the Invention

The present invention relates to a fabrication method for a semiconductor device in which a plurality of semiconductor chips are coupled with a substrate that serves as a supporting body.

Description of the Related Art

In order to implement further downsizing and higher integration of a semiconductor device, a three-dimensional mounting technology in which semiconductor chips are placed one on another in a thicknesswise direction and are coupled with each other by a through electrode (TSV: Through Silicon Via) has been put into practical use. However, in the three-dimensional mounting technology, a plurality of semiconductor chips are placed one on another in the thicknesswise direction, and therefore, the heat radiation characteristic is likely to degrade and semiconductor chips having different sizes cannot be used. Further, also there is a problem that the fabrication cost is likely to increase together with formation of through electrodes extending through the semiconductor chip.

In recent years, also a mounting technology in which a plurality of semiconductor chips are mounted on a substrate that functions as an interposer has been proposed (for example, refer to Japanese Translations of PCT for Patent No.2003-503855). This mounting technology is also called 2.5-dimensional mounting technology or the like, and, for example, a semiconductor chip having a memory function and another semiconductor chip having an arithmetic operation function are coupled with a substrate so as not to overlap with each other. In the 2.5-dimensional mounting technology, since at least part of semiconductor chips are not placed one on another in the thicknesswise direction, the problems of the three-dimensional mounting technology described above are likely to be solved.

### SUMMARY OF THE INVENTION

However, in the conventional 2.5-dimensional mounting technology, in order to couple an electrode and so forth provided on a substrate and a semiconductor chip with each other, a projecting terminal called micro bump must be formed on the semiconductor chip. Therefore, improvement is demanded in terms of the fabrication cost.

Therefore, it is an object of the present invention to provide a fabrication method for a semiconductor device in which there is no necessity to form a micro bump on a semiconductor chip.

In accordance with an aspect of the present invention, there is provided a fabrication method for a semiconductor device, including a semiconductor chip arraying step of arraying a plurality of semiconductor chips at given distances on a first face of a substrate that serves as a supporting body, a substrate thinning step of grinding a second face of the substrate at the side opposite to the first face to thin the substrate to a given thickness, a through electrode formation step of forming a through-hole that extends from the second face side to the semiconductor chip at a given position of the thinned substrate and embedding metal into the through-hole to form a through electrode, and a wiring layer formation step of forming a wiring layer at the second face side of the substrate.

In an embodiment of the present invention, preferably, at the through electrode formation step, a through electrode contacting with a coupling terminal formed on each of the semiconductor chips is formed.

In the fabrication method for a semiconductor device according to the present invention, different from the conventional technology, a through electrode is not formed in advance on a substrate but is formed after semiconductor chips are arrayed on a substrate. Therefore, even if a projecting terminal such as a micro bump is not provided, the through electrode can be coupled with the semiconductor chip. In short, with the fabrication method for a semiconductor device according to the present invention, since there is no necessity to form a micro bump on a semiconductor chip, the fabrication cost can be suppressed low.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view schematically depicting a manner in which a plurality of semiconductor chips are arrayed on a substrate;

FIG. 1B is a sectional view schematically depicting a substrate on which the plurality of semiconductor chips are arrayed;

FIG. 2A is a side elevational view, partly in section, schematically depicting a manner in which a sealing member is applied to a first face side of the substrate;

FIG. 2B is a sectional view schematically depicting the substrate whose first face side is sealed by a sealing layer;

FIG. 3A is a side elevational view, partly in section, schematically depicting a manner in which a second face of the substrate is ground;

FIG. 3B is a sectional view schematically depicting the substrate after it is thinned;

FIG. 4A is a sectional view schematically depicting a manner in which a through-hole is formed at a given position of the substrate;

FIG. 4B is a sectional view schematically depicting the substrate on which a through electrode is formed; and

FIG. 5 is a sectional view schematically depicting the substrate on which a wiring layer is formed.

### DETAILED DESCRIPTION OF THE PREFERRED EMBODIMENT

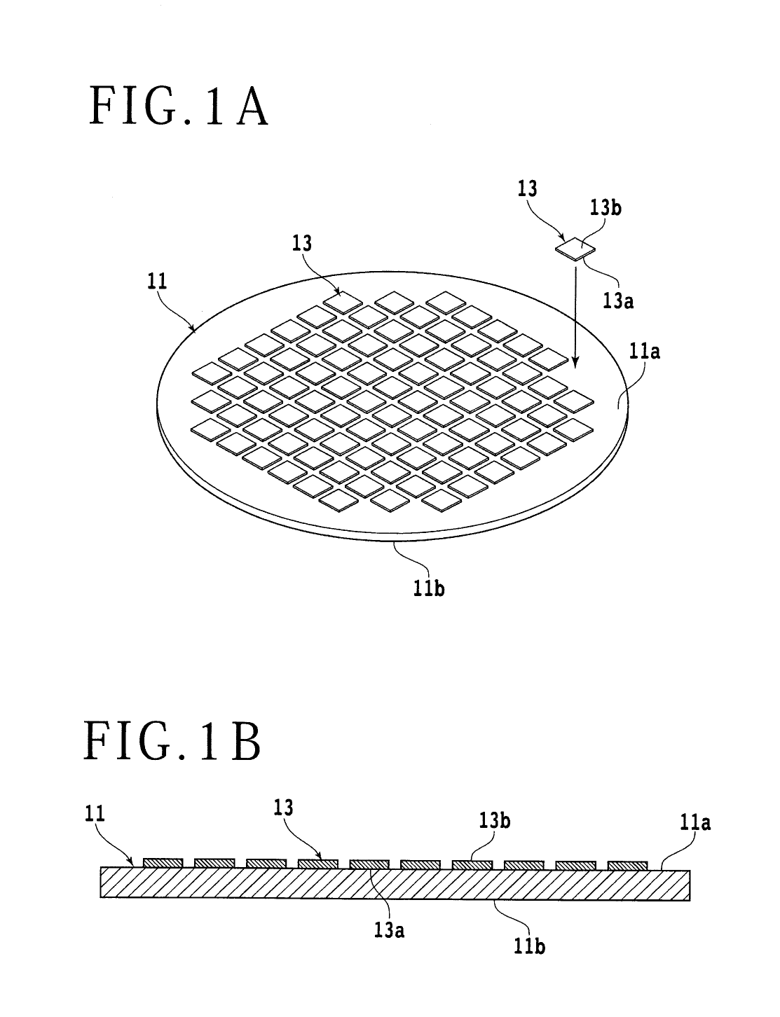

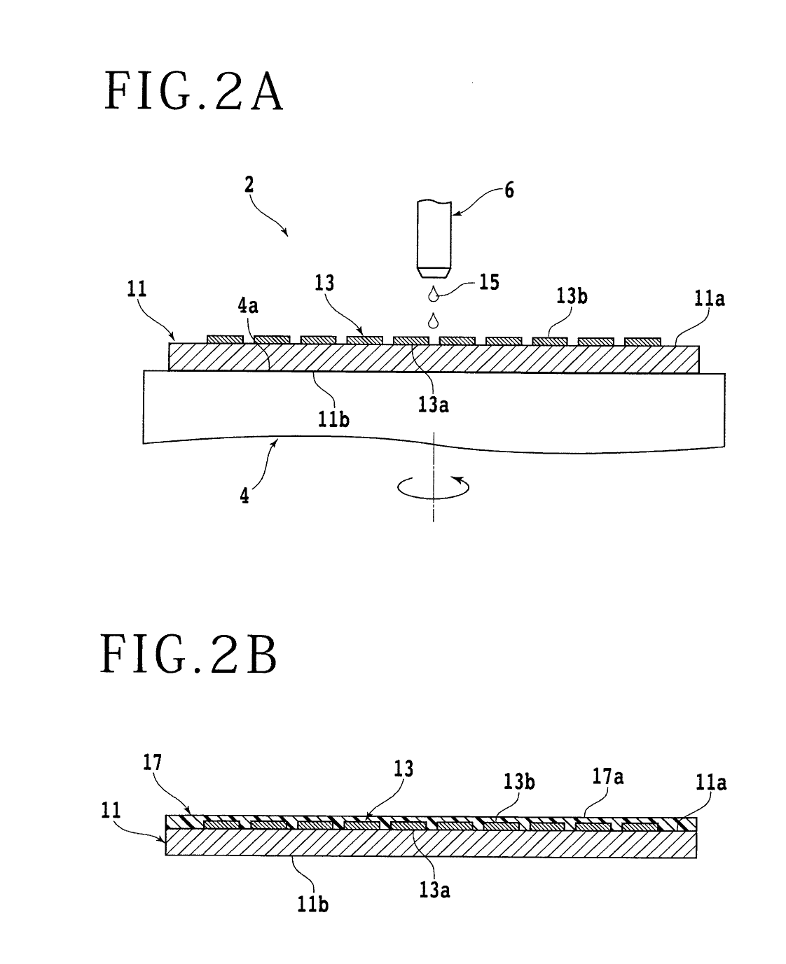

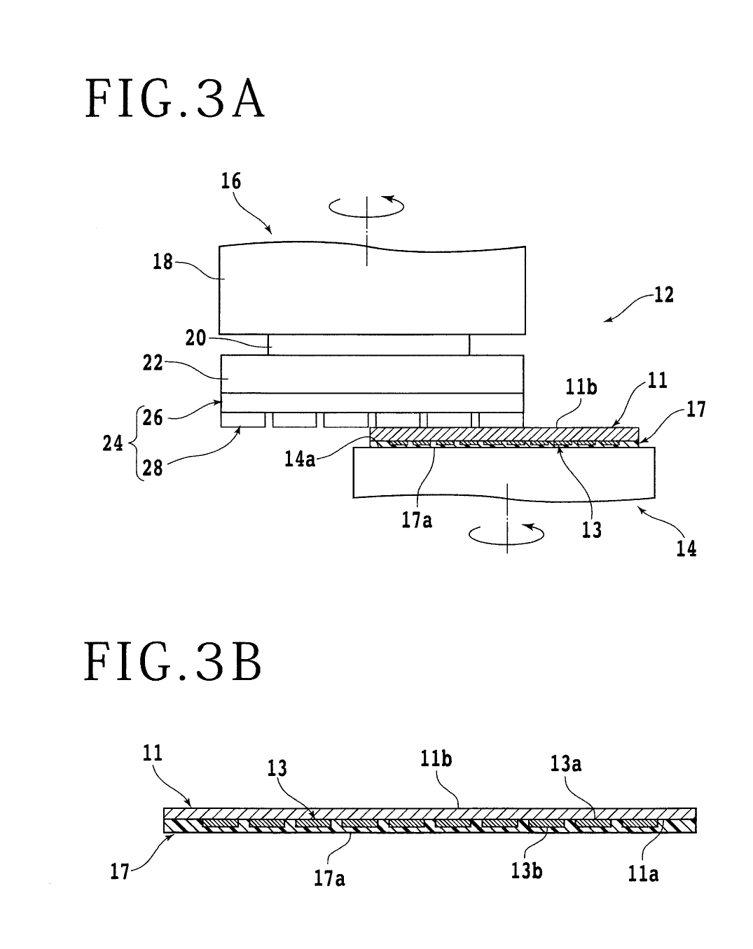

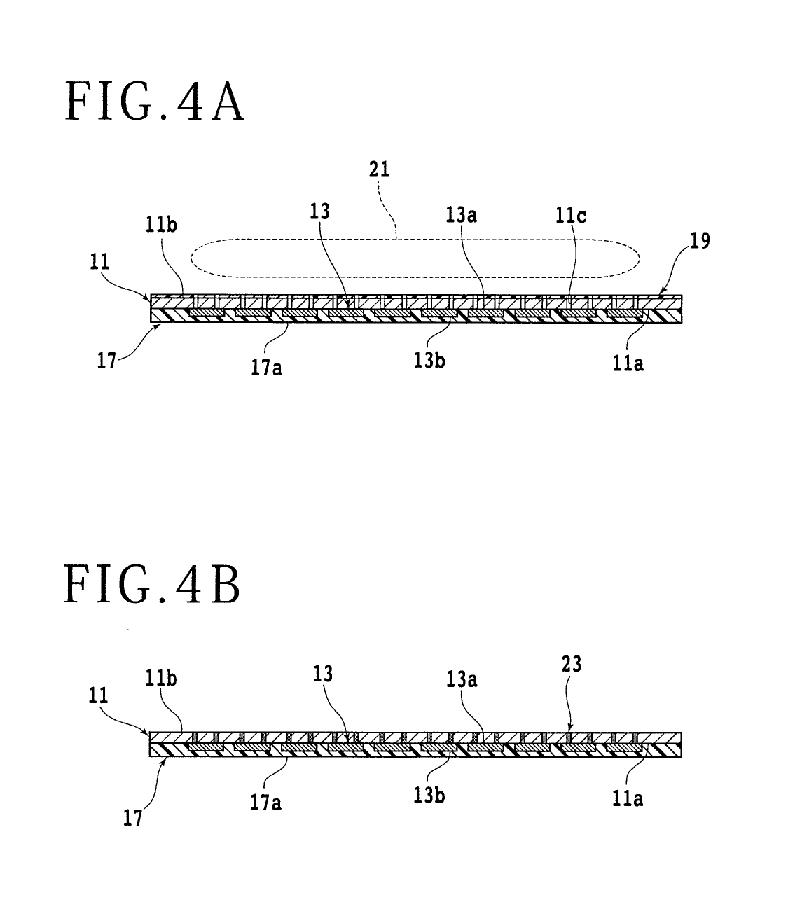

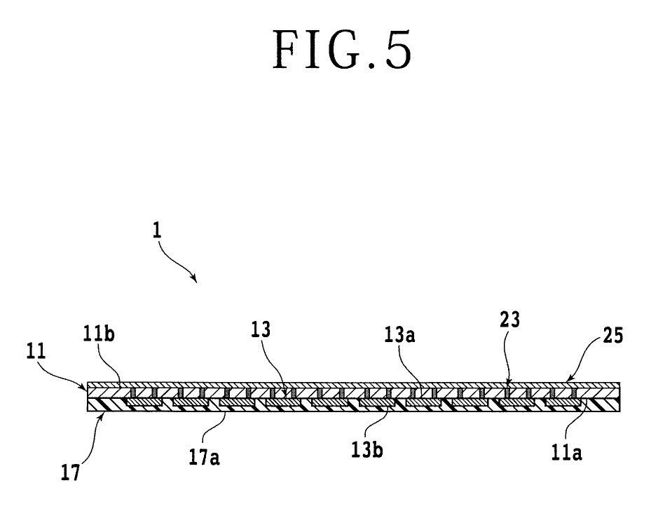

In the following, an embodiment of the present invention is described with reference to the accompanying drawings. A fabrication method for a semiconductor device according to the present embodiment includes a semiconductor chip arraying step (refer to FIGS. 1A and 1B), a sealing step (refer to FIGS. 2A and 2B), a substrate thinning step (refer to FIGS. 3A and 3B), a through electrode formation step (refer to FIGS. 4A and 4B), and a wiring layer formation step (refer to FIG. 5). At the semiconductor chip arraying step, a plurality of semiconductor chips are arrayed at given distances on a first face of a substrate that serves as a supporting body. At the sealing step, the first face side of the substrate on which the plurality of semiconductor chips are arrayed is sealed. At the substrate thinning step, a second face of the substrate at the side opposite to the first face is ground to thin the substrate to a given thickness. At the through electrode formation step, a through-hole extending from the second face side to the semiconductor chips is formed at a given position of the substrate, and metal is embedded into the through-hole to form a through electrode. At the wiring layer formation step, a wiring layer including a wiring line coupled with the through electrode is formed at the second face side of the substrate. The fabrication method for a semiconductor device according to the present embodiment is described below in detail.

In the fabrication method for a semiconductor device according to the present embodiment, the semiconductor chip arraying step of arraying a plurality of semiconductor chips on a substrate to be used as a supporting body is performed. FIG. 1A is a perspective view schematically depicting a manner in which a plurality of semiconductor chips 13 are arrayed on a substrate 11, and FIG. 1B is a sectional view schematically depicting the substrate 11 on which the plurality of semiconductor chips 13 are arrayed.

As depicted in FIG. 1A, the substrate 11 used in the present embodiment is formed in the form of a disk from a material such as silicon, and has a first face 11a and a second face 11b that are substantially flat. The substrate 11 becomes an interposer for coupling the plurality of semiconductor chips 13 and a wiring substrate (not depicted) or the like by forming through electrodes, a wiring layer and so forth later. It is to be noted that the material, shape and so forth of the substrate 11 are not limited specifically, and a substrate configured from a material such as, for example, ceramic (including glass or the like) or resin can be used. The plurality of semiconductor chips 13 individually include a memory function, an arithmetic operation function and so forth, and a coupling terminal (not depicted) for external coupling is provided at a first face 13a side of the semiconductor chips 13. In the present embodiment, the plurality of semiconductor chips 13 are arrayed on the substrate 11 such that the first face 13a each of the plurality of semiconductor chips 13 opposes to the first face 11a of the substrate 11.

Arraying of the semiconductor chips 13 on the substrate 11 is performed using an arbitrary chip arraying apparatus (not depicted). For example, at the first face 11a side of the substrate 11, a plurality of marks for defining the position of the semiconductor chips 13 are formed at given distances. The chip arraying apparatus arrays a plurality of semiconductor chips 13 at the given distances on the basis of the plurality of marks. For fixation of the semiconductor chips 13 to the substrate 11, for example, adhesive (not depicted) of the thermosetting type having heat resistance sufficient to withstand succeeding steps is used. The adhesive is shaped, for example, in the form of a semi-cured film, and is provided at the first face 11a side of the substrate 11 or the first face 13a side of the semiconductor chips 13. However, liquid adhesive or the like may be used. As depicted in FIGS. 1A and 1B, if all of the semiconductor chips 13 are arrayed at given distances on the first face 11a of the substrate 11 and the adhesive is hardened, then the semiconductor chip arraying step is ended. Since the first faces 13a of the semiconductor chips 13 oppose to the first face 11a of the substrate 11 as described above, a second face 13b each of the semiconductor chips 13 is exposed to the outside.

After the semiconductor chip arraying step, the sealing step of sealing the first face 11a side of the substrate 11 on which the plurality of semiconductor chips 13 are arrayed is performed. FIG. 2A is a side elevational view, partly in section, schematically depicting a manner in which a sealing member 15 is applied to the first face 11a side of the substrate 11, and FIG. 2B is a sectional view schematically depicting the substrate 11 on which the first face 11a side is sealed by a sealing layer 17.

At the sealing step, liquid sealing material 15 is applied to the first face 11a of the substrate 11 first. The application of the sealing material 15 is performed, for example, by a spin application apparatus 2 depicted in FIG. 2A. The spin application apparatus 2 includes a chuck table 4 for holding the second face 11b side of the substrate 11. The chuck table 4 is coupled with a rotational driving source (not depicted) such as a motor and rotates around a rotational axis extending substantially in parallel to the vertical direction. A top face of the chuck table 4 serves as a holding face 4a that sucks and holds the second face 11b side of the substrate 11. The holding face 4a is coupled with a suction source (not depicted) through a suction path (not depicted) or the like formed in the inside of the chuck table 4. The substrate 11 can be held on the chuck table 4 by causing a negative pressure of the suction source to act on the holding face 4a. A nozzle 6 which is configured from resin or the like having a heat resistance sufficient to withstand succeeding steps and allows dripping of the liquid sealing material 15 is disposed above the chuck table 4.

When the sealing material 15 is to be applied, the second face 11b side of the substrate 11 is contacted first with the holding face 4a of the chuck table 4 and a negative pressure of the suction source is caused to act upon the holding face 4a. Consequently, the substrate 11 is held on the chuck table 4 in a state in which the first face 11a side on which the plurality of semiconductor chips 13 are arrayed is exposed upwardly. It is to be noted that a protective tape or the like may be pasted on the second face 11b of the substrate 11. Then, the chuck table 4 is rotated and the liquid sealing material 15 is dripped from the nozzle 6. While, in the present embodiment, the sealing material 15 configured from epoxy-based resin is used, there is no limitation to the material of the sealing material 15. Consequently, the sealing material 15 can be applied to the first face 11a side of the substrate 11 on which the plurality of semiconductor chips 13 are arrayed. It is to be noted that it is desirable to apply the sealing material 15 so thick that the second faces 13b of the semiconductor chips 13 are covered. After the sealing material 15 is applied, a process such as drying or heating is performed to harden the sealing material 15. Consequently, the sealing layer 17 which seals the first face 11a side of the substrate 11 together with the plurality of semiconductor chips 13 is completed. It is to be noted that, after the sealing layer 17 is formed, it is desirable to flatten a surface 17a side of the sealing layer 17 by such a method as grinding or cutting. If the surface 17a of the sealing layer 17 is flat, then the second face 11b of the substrate 11 can be easily processed into a flat state at the succeeding substrate thinning step.

After the sealing step, the substrate thinning step of grinding the second face 11b of the substrate 11 to decrease the thickness of the substrate 11 to a given thickness is performed. FIG. 3A is a side elevational view, partly in section, schematically depicting a manner in which the second face 11b of the substrate 11 is ground, and FIG. 3B is a sectional view schematically depicting the substrate 11 after it is thinned.

The substrate thinning step is performed, for example, by a grinding apparatus 12 depicted in FIG. 3A. The grinding apparatus 12 includes a chuck table 14 for holding the surface 17a side of the sealing layer 17 formed on the substrate 11. The chuck table 14 is coupled with a rotational driving source (not depicted) such as a motor and rotates around a rotational axis extending substantially in parallel to the vertical direction. Further, a table movement mechanism (not depicted) is provided below the chuck table 14, and the chuck table 14 is moved in a horizontal direction by the table movement mechanism. The upper face of the chuck table 14 serves as a holding face 14a for sucking and holding the surface 17a of the sealing layer 17 formed on the substrate 11.

The holding face 14a is coupled with a suction source (not depicted) through a suction path (not depicted) or the like formed in the inside of the chuck table 14. The substrate 11 can be held on the chuck table 14 by causing the negative pressure of the suction source to act on the holding face 14a.

A grinding unit 16 is disposed above the chuck table 14. The grinding unit 16 includes a spindle housing 18 supported on a grinding unit lifting mechanism (not depicted). A spindle 20 is accommodated in the spindle housing 18, and a mount 22 in the form of a disk is fixed at a lower end portion of the spindle 20. A grinding wheel 24 having a diameter substantially equal to that of the mount 22 is mounted on a lower face of the mount 22. The grinding wheel 24 includes a wheel base 26 formed from a metal material such as stainless steel or aluminum. A plurality of grinding stones 28 are arrayed annularly on the lower face of the wheel base 26. A rotational driving source (not depicted) such as a motor is coupled with an upper end side (base end side) of the spindle 20. The grinding wheel 24 is rotated around a rotational axis extending substantially in parallel to the vertical direction by the rotational force transmitted from the rotational driving source.

At the substrate thinning step, the surface 17a side of the sealing layer 17 formed on the substrate 11 is contacted with the holding face 14a of the chuck table 14 so as to cause a negative pressure of the suction source to act on the substrate 11. Consequently, the substrate 11 is held on the chuck table 14 in a state in which the second face 11b side thereof is exposed upwardly. It is to be noted that a protective tape or the like may be pasted in advance on the surface 17a of the sealing layer 17. Then, the chuck table 14 is moved to a position below the grinding wheel 24. Then, as depicted in FIG. 3A, the chuck table 14 and the grinding wheel 24 are rotated to move down the spindle housing 18 while grinding fluid such as pure water is supplied. The downward movement amount of the spindle housing 18 is adjusted to such a degree that the lower face of the grinding stones 28 is pressed against the second face 11b of the substrate 11. Consequently, the second face 11b side of the substrate 11 can be ground. This grinding is performed, for example, while the thickness of the substrate 11 is measured. If the substrate 11 is thinned to a finish thickness as depicted in FIG. 3B, then the substrate thinning step is ended.

After the substrate thinning step, the through electrode formation step of forming a through electrode at a given position of the substrate 11 is performed. FIG. 4A is a sectional view schematically depicting a manner in which through-holes 11c are formed at given positions of the substrate 11, and FIG. 4B is a sectional view schematically depicting the substrate 11 on which through electrodes 23 are formed.

At the through electrode formation step according to the present embodiment, a resist film 19 that covers the second face 11b of the substrate 11 is formed first. The resist film 19 is formed by such a method as, for example, photolithography such that regions at the second face 11b side in which the through-holes 11c are to be formed are exposed, and has a withstanding property against later plasma etching. After the resist film 19 is formed, as depicted in FIG. 4A, the exposed regions of the substrate 11 at the second face 11b side are worked by plasma etching to form through-holes 11c. In particular, for example, a processing space of a vacuum chamber (not depicted) into which the substrate 11 is carried is decompressed to supply raw material gas for plasma etching at a predetermined flow rate. If, in this state, predetermined high frequency power is supplied to electrodes (not depicted) in the processing space, then plasma 21 including radicals and ions is generated. If the plasma 21 is caused to act upon the exposed region of the substrate 11, then the substrate 11 in the regions (and the adhesive) is removed. Consequently, through-holes 11c can be formed which extend from the second face 11b side of the substrate 11 to the first face 13a of the semiconductor chips 13. It is to be noted that the through-holes 11c are formed at positions corresponding to coupling terminals of the semiconductor chips 13. The conditions such as the type and the supply amount of the raw material gas for plasma etching, high frequency power to be supplied to the electrodes and so forth are set appropriately in response to the material of the substrate 11, the size of the through-holes 11c and so forth. For example, when through-holes 11c are to be formed in a substrate 11 made of silicon, mixture gas of SF₆, O₂, inertia gas and so forth may be used as the raw material gas.

After the through-holes 11c are formed, the resist film 19 is removed by such a method as asking, and metal is embedded into the through-holes 11c to form through electrodes 23 as depicted in FIG. 4B. In particular, for example, an insulating film (not depicted) that covers a side wall (inner wall) of the through-holes 11c is formed, and then through electrodes 23 contacting with the coupling terminals of the semiconductor chips 13 are provided. Although there is no limitation to the formation method of the insulating film and the through electrodes 23, for example, a chemical vapor deposition (CVD) method, a sputtering method, a vacuum vapor deposition method and so forth can be used. The insulating film is formed using, for example, silicon dioxide (SiO₂), silicon nitride (Si₃N₄), silicon oxynitride (SiOₓN_{y}), oxides or nitrides (including oxynitrides) of various metals and so forth. Meanwhile, the through electrodes 23 are formed using titanium (Ti), tantalum (Ta), tungsten (W), aluminum (Al), copper (Cu) or the like. It is to be noted, however, that there is no limitation to the material of the insulating film and the through electrodes 23, and the material can be changed arbitrarily in response to specifications and so forth.

After the through electrode formation step, the wiring layer formation step of forming a wiring layer including wiring lines coupled to the through electrodes 23 on the second face 11b side of the substrate 11 is performed. FIG. 5 is a sectional view schematically depicting the substrate 11 on which a wiring layer 25 is formed. The wiring layer 25 includes an insulating film (not depicted), wiring lines (not depicted) and so forth that are formed by such a method as, for example, a CVD method, a sputtering method, a vacuum vapor deposition method and so forth. By the wiring layer 25, the through electrodes 23 and an external wiring substrate (not depicted) or the like can be electrically coupled with each other. It is to be noted that there is no limitation to the formation method, formation conditions and so forth of the wiring layer 25, and an appropriate method and conditions can be suitably used in combination. After the wiring layer 25 is formed, the wiring layer formation step is ended, and a semiconductor device 1 according to the present embodiment is completed. It is to be noted that the semiconductor device 1 after the completion may be divided into arbitrary units by dicing or the like.

As described above, with the fabrication method for a semiconductor device according to the present embodiment, different from the conventional technology, the through electrodes 23 are not formed in advance on the substrate 11, but the through electrodes 23 are formed after the semiconductor chips 13 are arrayed on the substrate 11. Therefore, even if a projecting terminal such as a micro bump is not provided, the through electrodes 23 can be connected to the semiconductor chips 13. In short, with the fabrication method for a semiconductor device according to the present embodiment, since there is no necessity to form a micro bump on the semiconductor chips 13, the fabrication cost can be suppressed low.

It is to be noted that the present invention is not limited to the description of the embodiment described hereinabove but can be carried out in various modified forms. For example, while, in the embodiment described above, the sealing step is performed after the semiconductor chip arraying step, also it is possible to omit the sealing step. Where the sealing step is omitted, preferably a protective tape or the like is pasted in advance to the second face 13b side of the semiconductor chips 13 such that the semiconductor chips 13 and so forth may not be damaged at the substrate thinning step and so forth. Further, although, at the through electrode formation step in the embodiment described above, the through-holes 11c are formed in the substrate 11 using plasma etching, also it is possible to form the through-holes 11c in the substrate 11 by such a method as laser processing or drilling.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A fabrication method for a semiconductor device, comprising:
a semiconductor chip arraying step of arraying a plurality of semiconductor chips at given distances on a first face of a substrate that serves as a supporting body;
a substrate thinning step of grinding a second face of the substrate at the side opposite to the first face to thin the substrate to a given thickness;
a through electrode formation step of forming a through-hole that extends from the second face side to the semiconductor chip at a given position of the thinned substrate and embedding metal into the through-hole to form a through electrode; and
a wiring layer formation step of forming a wiring layer at the second face side of the substrate.

2. The fabrication method for a semiconductor device according to claim 1,
wherein, at the through electrode formation step, a through electrode contacting with a coupling terminal formed on each of the semiconductor chips is formed.
